(19) United States
(12) Patent Application Publication
(10) Pub. No.: US 2026/0250546 A1
(43) Pub. Date: Aug. 27, 2026

(54) DECONTAMINATION MATERIAL AND MANUFACTURING METHOD THEREOF, METHOD FOR CLEANING A PROBE PIN

(71) Applicant: Alliance Material Co., Ltd., Hsinchu County (TW)

(72) Inventors: Yu-Hsuen Lee, Hsinchu County (TW); Ching-Wen Hsu, Hsinchu County (TW); Chao-Hsuan Yang, Hsinchu County (TW); Ting-Wei Lin, Hsinchu County (TW); Chun Fa Chen, Hsinchu County (TW); Hsueh Chung Wu, Hsinchu County (TW)

(73) Assignee: Alliance Material Co., Ltd., Hsinchu County (TW)

(21) Appl. No.: 19/645,307

(22) Filed: Apr. 13, 2026

Related U.S. Application Data
(63) Continuation-in-part of application No. 18/506,139, filed on Nov. 10, 2023, now Pat. No. 12,674,819.
Application No. 18/506,139 is a continuation-in-part of application No. 17/691,129, filed on Mar. 10, 2022, now Pat. No. 11,865,588.
Application No. 17/691,129 is a continuation-in-part of application No. 17/095,747, filed on Nov. 12, 2020, now abandoned.
(63) Continuation-in-part of application No. 19/363,655, filed on Oct. 21, 2025.
(60) Provisional application No. 62/933,990, filed on Nov. 12, 2019.

(30) Foreign Application Priority Data
Mar. 2, 2020 (TW) 109106766
Oct. 22, 2020 (TW) 109136656
Sep. 23, 2023 (TW) 112136486
Sep. 23, 2025 (TW) 114136540
Mar. 5, 2026 (TW) 115108044

(51) Int. Cl. C09D 183/04; C09D 7/61; C09D 7/63; G01R 3/00

(52) U.S. Cl. CPC C09D 183/04; C09D 7/61; C09D 7/63; G01R 3/00

(57) ABSTRACT

A decontamination material including a support layer and a cleaning layer is provided. The cleaning layer is disposed on the support layer. The cleaning layer is made of resin, a plurality of cleaning particles dispersed in the resin, and a plurality of abrasive particles dispersed in the resin. The cleaning particles have a Mohs hardness of less than 7. The abrasive particles have a Mohs hardness of greater than or equal to 7. A manufacturing method for the decontamination material is also proposed. A method for cleaning a probe pin is also proposed.

### CROSS-REFERENCE TO RELATED APPLICATION

This application is a continuation-in-part application of U.S. patent application Ser. No. 18/506,139, filed on Nov. 10, 2023, now allowed, and U.S. patent application Ser. No. 19/363,655, filed on Oct. 21, 2025, now pending. The U.S. patent application Ser. No. 19/363,655 claims the priority benefit of Taiwan application serial no. 114136540, filed on Sep. 23, 2025. The U.S. patent application Ser. No. 18/506,139 is a continuation-in-part application of U.S. patent application Ser. No. 17/691,129, filed on Mar. 10, 2022, now U.S. Pat. No. 11,865,588 B2. The U.S. patent application Ser. No. 18/506,139 also claims the priority benefit of Taiwan application serial no. 112136486, filed on Sep. 23, 2023. The U.S. patent application Ser. No. 17/691,129 is a continuation-in-part application of U.S. patent application Ser. No. 17/095,747, filed on Nov. 12, 2020, now abandoned, which claims the priority benefits of U.S. provisional application Ser. No. 62/933,990, filed on Nov. 12, 2019, Taiwan application serial no. 109106766, filed on Mar. 2, 2020, and Taiwan application serial no. 109136656, filed on Oct. 22, 2020. This application also claims the priority benefit of Taiwan application serial no. 115108044, filed on Mar. 5, 2026. The entirety of each of the above-mentioned patent applications is hereby incorporated by reference herein and made a part of this specification.

### BACKGROUND

### Technical Field

The present disclosure relates to a decontamination material and a method for manufacturing the same, and particularly relates to a decontamination material that may be used for probe cleaning and a method for manufacturing the same.

### Description of Related Art

In the process of semiconductor wafer testing (Chip Probing, CP) or final testing (Final Test, FT), probes need to repeatedly contact pads or bumps on wafers to conduct electrical testing. As the number of tests increases, probe tips easily accumulate metal debris, oxides, or other organic contaminants, causing unstable contact resistance (Contact Resistance, Cres), which in turn affects test yield. Therefore, how to effectively clean probes to maintain their testing performance has become an important issue in the semiconductor testing field.

### SUMMARY

Some embodiments of the present disclosure provide a decontamination material and a manufacturing method thereof. The decontamination material is configured to effectively clean probe pins or remove contaminants therefrom.

The decontamination material of some embodiments of the present disclosure includes a support layer and a cleaning layer. The cleaning layer is disposed on the support layer. The cleaning layer includes a resin, a plurality of cleaning particles dispersed in the resin, and a plurality of abrasive particles dispersed in the resin. The Mohs hardness of the cleaning particles is less than 7. The Mohs hardness of the abrasive particles is greater than or equal to 7.

A method for manufacturing the decontamination material of some embodiments of the present disclosure includes: providing a support layer; mixing resin, a plurality of cleaning particles, and a plurality of abrasive particles to form a coating solution, wherein the Mohs hardness of the cleaning particles is less than 7, and the Mohs hardness of the abrasive particles is greater than or equal to 7; coating the coating solution on the support layer; and curing the coating solution to form a cleaning layer, wherein the curing temperature is between 80° C. and 160° C., and the curing time is between 5 minutes and 90 minutes.

A method for cleaning a probe pin includes: providing the aforementioned decontamination material; penetrating the probe into the cleaning layer of the decontamination material, wherein a substance adhered to the probe rubs against the abrasive particles in the cleaning layer and is detached from the probe; and separating the probe from the cleaning layer of the decontamination material, wherein the resin and the cleaning particles actively trap and encapsulate the substance detached from the probe within the resin, thereby mitigating a possibility of the substance re-adhering to the probe.

Accordingly, the resin matrix synergistically encapsulates and anchors both the cleaning particles and the abrasive particles onto the support layer, forming a robust cleaning layer. This structural configuration unexpectedly improves the cleaning efficacy while preserving the structural integrity of the probes.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic partial cross-sectional view of a decontamination material according to an embodiment of the present disclosure.

FIG. 2A to FIG. 2F are schematic views illustrating a usage method of a decontamination material according to an embodiment of the present disclosure.

FIG. 3A to FIG. 3C are partial cross-sectional enlarged schematic views illustrating a usage method of a decontamination material according to an embodiment of the present disclosure.

FIG. 4A is a partial cross-sectional enlarged view of a decontamination material according to [Comparative Example] after probe cleaning.

FIG. 4B is a partial cross-sectional enlarged view of a decontamination material according to [Experimental Example 2] after probe cleaning.

### DESCRIPTION OF THE EMBODIMENTS

The directional terms used herein (for example: up, down, right, left, top, bottom) are used only with reference to the drawings and are not intended to imply absolute orientation.

The non-limiting terms used in the specification (for example: approximately, substantially, generally, may, might, can) may be expressions of an embodiment, and the content or numerical values they represent may be within an acceptable deviation range for those of ordinary skill in the art. For example, the numerical values represented may include the stated values as well as deviation values within the deviation range acceptable to those having ordinary knowledge in the art. The aforementioned deviation values may be one or more standard deviations in the manufacturing process or measurement process, or calculation errors generated by other factors such as the number of digits used, rounding, or error propagation in the calculation or conversion process.

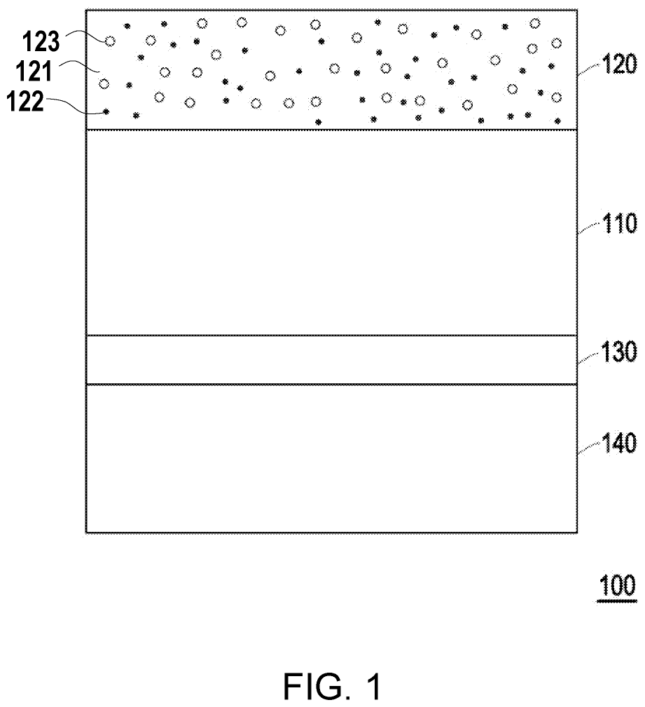

FIG. 1 is a schematic partial cross-sectional view of a decontamination material according to an embodiment of the present disclosure. As used herein, the term “decontamination material” may be broadly referred to as a cleaning pad, a cleaning sheet, a polishing film, or a multi-functional cleaning substrate, configured for semiconductor testing equipment (e.g., localized probe pins cleaning); but is expressly distinguished from and substantially not intended for use as a chemical mechanical polishing (CMP) pad.

Referring to FIG. 1, the decontamination material 100 may include a laminated structure, which may include a support layer 110 and a cleaning layer 120. In an embodiment, the support layer 110 may serve as the supporting main structure of the decontamination material 100, and its function is to provide sufficient mechanical strength and stability. The cleaning layer 120 may be stacked on the support layer 110. The cleaning layer 120 may be regarded as a single film layer. That is, the materials included in the cleaning layer 120 are substantially uniformly distributed.

In an embodiment, the decontamination material 100 may optionally further include an adhesive layer 130. The adhesive layer 130 and the cleaning layer 120 are respectively located on two opposite sides of the support layer 110. In detail, the adhesive layer 130 is located on one side of the support layer 110 (such as the lower side in the figure), and its main function is to provide stable adhesion so that the decontamination material 100 could be fixed on a work surface or the surface of specific equipment.

In an embodiment, the decontamination material 100 may optionally further include a release layer 140, which covers one side of the adhesive layer 130 away from the support layer 110, for protecting the adhesive layer 130 when not in use, reducing or avoiding contamination with dust or loss of adhesiveness.

### <Support Layer>

The support layer 110 may be regarded as the main structure of the decontamination material 100. One function of the support layer 110 is to provide sufficient mechanical strength, dimensional stability, or chemical stability to support the film layers thereon. In an embodiment, the support layer 110 may also be referred to as a substrate. In order to balance structural support, processability, and flexibility in practical applications, the thickness of the support layer 110 may be appropriately selected. In an embodiment, the thickness of the support layer 110 may be between approximately 50 micrometers (μm) to approximately 8000 micrometers. For example, the thickness of the support layer 110 may be substantially approximately 100 micrometers.

The thickness range setting of the support layer 110 has its technical considerations. If the thickness of the support layer 110 is less than 50 micrometers, the rigidity and support it provides may be poor, and wrinkles or deformation may easily occur during operation or transfer processes; and during the probe cleaning process, the thinner support layer 110 may easily be damaged due to the downward external force of the probe, and may even cause the probe to penetrate the decontamination material 100 and damage the underlying stage. On the other hand, if the thickness of the support layer 110 is greater than 8000 micrometers, the overall thickness of the decontamination material 100 may become excessively thick, which not only leads to increased material costs, but may also exceed the specification limits of semiconductor-related equipment (such as: trays or transfer equipment such as transfer arms; such as: test equipment such as test stages), or affect the conformability of bonding due to excessive rigidity, thereby reducing the applicability of the product.

In order to achieve the required physical properties and adapt to different test environments (such as: high and low temperature test environments), the material of the support layer 110 may be selected from materials with good temperature resistance and chemical resistance. In an embodiment, the material of the support layer 110 may include polyethylene terephthalate (PET), polyimide (PI), polyetheretherketone (PEEK), polyetherimide (PEI), polyamide (PA), polyethersulfone (PES), polyethylene naphthalate (PEN), wafers (such as: silicon wafers), glass, metal plates, glass fiber boards (such as: FR4), ceramic plates, or stacking or combinations of the above materials. For example, if the decontamination material 100 is applied in high temperature test environments, polyimide, polyetheretherketone, ceramics, or wafers with better heat resistance may be selected as the material of the support layer 110.

### <Adhesive Layer>

The adhesive layer 130 may be disposed below the support layer 110 (lower side in FIG. 1). One function of the adhesive layer 130 is to provide stable adhesion force, so as to temporarily or permanently fix the decontamination material 100 on the surface of an appropriate object (such as: work surfaces such as stages; substrates simulating wafers or objects such as dummy chips), ensuring that the decontamination material 100 will not experience unexpected displacement or sliding during probe cleaning operations.

In an embodiment, the thickness of the adhesive layer 130 may be appropriately selected. For example, the thickness of the adhesive layer 130 may be between 10 micrometers (μm) to 50 micrometers. For example, the thickness of the adhesive layer 130 may be substantially 25 micrometers. This thickness range is selected to provide technical advantages. For example, if the thickness of the adhesive layer 130 is less than 10 micrometers, it may cause insufficient coating amount of adhesive, unable to provide sufficient surface wetting force and grip, causing the decontamination material 100 to fall off when subjected to lateral forces from probe scraping; on the other hand, if the thickness of the adhesive layer 130 is greater than 50 micrometers, in addition to increasing material costs, the excessively thick adhesive layer may experience oozing phenomenon when subjected to pressure, contaminating the machine stage, or affecting the overall flatness (Total Thickness Variation, TTV) of the decontamination material 100 due to uneven adhesive layer thickness.

In order to adapt to different operating environments (such as: high temperature test environments or general room temperature environments), the material type of the adhesive layer 130 may be appropriately selected. In an embodiment, the material of the adhesive layer 130 may include acrylic resin, silicone resin, rubber-based resin, polyurethane resin, or combinations thereof.

For example, if considering cost and adhesion force under general environments, acrylic resin may be optionally selected, which may be formed by copolymerization of monomers such as butyl acrylate and isooctyl acrylate, with addition of isocyanate or epoxy resin as crosslinking agent. For example, if applied to semiconductor high temperature test processes, silicone resin with better heat resistance may be optionally selected, such as addition-type silicone resin or peroxide-type silicone resin, to reduce or avoid adhesive residue occurrence at high temperatures.

The adhesion force of the adhesive layer 130 may be appropriately selected, for example controlled between 100 gf/25 mm to 2000 gf/25 mm (according to JIS Z 0237 standard test). This range could ensure decontamination material 100 could be firmly adhered, and could be easily removed during replacement without leaving adhesive residue on the corresponding object.

In an embodiment, regarding the formation method of the adhesive layer 130, direct coating or transfer coating may be adopted according to process requirements. In the direct coating method, the liquid adhesive composition is directly coated on the surface of the support layer 110, and forms a film through drying or curing (such as: thermal curing or UV curing). In the transfer coating method, the adhesive is first coated on a release carrier, and after drying or curing, it is then transferred and laminated onto the support layer 110 by means of a laminating roller.

The coating technology used to form the adhesive layer 130 may be appropriately selected to ensure thickness uniformity. Applicable coating methods include but are not limited to: slot-die coating, micro-gravure coating, comma coating, roll coating, or screen printing. By means of the aforementioned appropriate coating technologies, the thickness error of the adhesive layer 130 may be controlled within a minute range (such as: within +2 micrometers) to meet the requirements of precision testing.

### <Release Layer>

In an embodiment, if the decontamination material 100 is provided with an adhesive layer 130, a release layer 140 may be optionally further configured. The release layer 140 covers one side of the adhesive layer 130 away from the support layer 110 (the lower side in FIG. 1). One function of the release layer 140 is to protect the surface of the adhesive layer 130 when the decontamination material 100 has not yet been used or attached to an appropriate object, to reduce or avoid contamination due to contact with dust in the air, or to avoid loss of adhesiveness or unnecessary adhesion due to accidental contact. During use, the user could easily remove the release layer 140 to expose the adhesive layer 130 for attachment and fixation.

The material of the release layer 140 may be appropriately selected. In an embodiment, the release layer 140 may include polymer film or paper. The material of the polymer film includes, for example, polyethylene terephthalate (PET), polypropylene (PP), polyethylene (PE), or polystyrene (PS). The material of the paper includes, for example, glassine paper, kraft paper, or poly-coated paper. To achieve an appropriate release effect (e.g., easy separation from the adhesive layer 130), the surface of the release layer 140 in contact with the adhesive layer 130 may be subjected to release treatment, such as coating with a release agent. The type of release agent may be appropriately selected according to the material characteristics of the adhesive layer 130. For example, if the adhesive layer 130 is an acrylic or rubber-based adhesive, a silicone-based release agent may be selected; if the adhesive layer 130 is a silicone-based adhesive, a fluorine-based release agent or a long-chain alkyl-based release agent (non-silicone release agent) may be selected to ensure appropriate peel force between the two.

The physical characteristics of the release layer 140 (such as: thickness and release force) may be appropriately selected to balance protection and operational convenience. In an embodiment, the thickness of the release layer 140 may be between 25 micrometers and 175 micrometers. This thickness range is selected to provide technical advantages. For example, if the thickness of the release layer 140 is less than 25 micrometers, the film rigidity is insufficient, and breakage or curling easily occurs during the removal process, causing operational inconvenience; if the thickness of the release layer 140 is greater than 175 micrometers, it may increase unnecessary material cost and overall thickness, and it is more difficult to store by curling.

Furthermore, the release force of the release layer 140 may also be appropriately selected. The release force of the release layer 140 to the adhesive layer 130 is less than the adhesive force of the adhesive layer 130 to the support layer 110. In an embodiment, the release force of the release layer 140 to the adhesive layer 130 may be between 2 gf/25 mm and 200 gf/25 mm. If the release force is less than 2 gf/25 mm, the release layer 140 may undergo pre-peeling during cutting, transportation, or storage due to excessively low adhesion, causing the adhesive layer 130 to be exposed and fail; if the release force is greater than 200 gf/25 mm, the release layer 140 and adhesive layer 130 are bonded too tightly (heavy release), requiring users to apply greater force when removing, which may cause the decontamination material 100 to wrinkle or deform, affecting subsequent flatness.

Regarding the formation method and attachment method of the release layer 140, a plurality of process means may be adopted. In an embodiment, a release agent may be coated on an appropriate substrate by coating methods (such as: gravure coating, knife coating, Mayer Rod coating), and the release layer 140 may be formed through thermal curing or UV curing; subsequently, lamination technology may be utilized to attach the pre-prepared release layer 140 to the support layer 110 that has been coated with the adhesive layer 130. In another embodiment (transfer coating method), the adhesive layer 130 may also be first coated on the release surface of the release layer 140, and after the adhesive layer 130 is dried or cured, it may be transferred and attached to the support layer 110.

### <Cleaning Layer>

Referring to FIG. 1, the cleaning layer 120 is disposed on the support layer 110 (upper side in FIG. 1). The cleaning layer 120 is the main functional layer for performing cleaning operations in an embodiment. In structural composition, the cleaning layer 120 uses resin 121 as a matrix or binder, and is mixed to include a plurality of cleaning particles 122 and a plurality of abrasive particles 123 dispersed therein. The resin 121 fixes the cleaning particles 122 and abrasive particles 123 on the support layer 110, forming a film layer with appropriate cleaning function.

The thickness of the cleaning layer 120 may be appropriately selected to match the tip length of the probe to be cleaned or the overdrive stroke of the machine. In an embodiment, the thickness of the cleaning layer 120 may be between 10 micrometers and 400 micrometers. For example, the thickness of the cleaning layer 120 may be substantially 250 micrometers. This thickness range is selected to provide technical advantages. For example, if the thickness of the cleaning layer 120 is less than 10 micrometers, when the probe performs downward pressing cleaning, the needle tip easily penetrates the cleaning layer 120 and contacts the support layer 110 below, resulting in poor cleaning effect or causing needle tip damage; if the thickness of the cleaning layer 120 is greater than 400 micrometers, the overall film thickness may be too thick, making thickness uniformity difficult to control during the coating process, or causing unnecessary stress residue during the curing process.

### <Cleaning Particles>

The cleaning particles 122 (or may be called first particles, soft particles) are mainly distributed in the resin 121, used to provide buffering action during the cleaning process and adsorption action for fine contaminants. In order to reduce or avoid excessive wear on the probe surface during the cleaning process, the hardness of the cleaning particles 122 may be appropriately selected. For example, the Mohs hardness of the cleaning particles 122 is less than 7. Due to the relatively low hardness of the cleaning particles 122, when the probe penetrates the cleaning layer 120, the cleaning particles 122 could form elastic encapsulation or soft contact around the probe, helping to remove dirt with weak adhesion while absorbing part of the impact force when the probe contacts the cleaning layer 120.

The chemical composition and surface properties of the cleaning particles 122 may have an impact on the compatibility with the resin 121 and the adsorption force for contaminants. In an embodiment, the types of cleaning particles 122 may include compounds or glass containing specific organic functional groups. The specific organic functional groups include, for example: alkenyl, ether, amide, amino, carboxyl, ester, alcohol, silane, alkoxy, alkoxysilane, or combinations thereof.

For example, the cleaning particles 122 may be organic polymer particles that inherently contain the aforementioned functional groups, for example, crosslinked polymethyl methacrylate (PMMA) particles or polystyrene (PS) particles. Alternatively, the cleaning particles 122 may be surface-modified inorganic particles. For example, glass microspheres may be surface-modified in an appropriate manner (such as: using silane coupling agents for surface grafting reactions) to make their surfaces have corresponding alkenyl, ether, amide, amino, carboxyl, ester, alcohol, silane, alkoxy, or alkoxysilane groups. Through the presence of the aforementioned functional groups, the interfacial bonding force between the cleaning particles 122 and the resin 121 may be enhanced, preventing or reducing particle fall-out during operation.

The morphology of the cleaning particles 122 may be appropriately selected, for example, spherical or polygonal (irregular). The particle size distribution (such as D50 particle size) of the cleaning particles 122 may be between 0.05 micrometers and 30 micrometers. The selection of this particle size range may be to ensure that the particles could effectively enter the fine grooves on the probe surface for cleaning. If the particle size is too large, the contact area decreases; if the particle size is too small, it is difficult to achieve the effect of physical wiping.

In an embodiment, in order to make the surface of the cleaning particles 122 carry specific functional groups (such as: alkenyl, ether, amide, amino, carboxyl, ester, alcohol, silane, alkoxy, or alkoxysilane groups), surface modification treatment may be performed on the cleaning particles 122. The modification method may be appropriately selected according to the original material (inorganic or organic) of the cleaning particles 122. Additionally, these functional groups will directly participate in crosslinking reactions during the curing process of the resin 121 (for example, during hydrosilylation reactions), causing appropriate bonding (such as: covalent bonds or Van der Waals forces) to form between the particle surface and the resin network structure. This interfacial chemical anchoring technology solves the possibility of interfacial delamination that easily occurs under repeated thermal cycling in traditional decontamination materials due to different coefficients of thermal expansion (CTE) between particles and matrix (e.g., resin).

In an embodiment, when the original material of the cleaning particles 122 is selected from inorganic materials such as glass beads, since their surfaces are usually rich in hydroxyl groups (—OH), it is suitable to use silane coupling agents for surface grafting modification. For example, the general structural formula of silane coupling agents is Y—R—Si—X₃₋ₙHₙ. Where n is 0, 1, 2; X is a hydrolyzable group (such as: methoxy, ethoxy), which after hydrolysis could undergo condensation reactions with hydroxyl groups on the inorganic particle surface to form stable silicon-oxygen bonds (Si—O-M, where M is the surface atom of the particle); Y is an organic functional group, namely the aforementioned target groups such as alkenyl and amino groups; R is a linking group.

In order to introduce specific functional groups, the type of silane coupling agent may be appropriately selected. For example, if it is desired to introduce alkenyl groups, vinyltrimethoxysilane or vinyltriethoxysilane may be selected. For example, if it is desired to introduce amino groups, 3-aminopropyltriethoxysilane (APTES) or N-2-(aminoethyl)-3-aminopropyltrimethoxysilane may be selected. For example, if it is desired to introduce epoxy groups (which may be regarded as a precursor or form of ether groups), 3-glycidoxypropyltrimethoxysilane may be selected. For example, if it is desired to introduce ester groups (such as methacryloxy groups), 3-methacryloxypropyltrimethoxysilane may be selected. For example, if it is desired to introduce carboxyl or alcohol groups, silane coupling agents containing anhydride or epoxy groups may first be used to modify the particle surface, and then obtained through hydrolysis ring-opening reactions or secondary reactions with polyols/polyacids for conversion.

In an embodiment, regarding exemplary implementation methods for surface modification, wet method or dry method may be adopted.

In the aforementioned wet method, the raw material particles used to make cleaning particles 122 may first be dispersed in a solvent (such as: water, ethanol or their mixture) to form a slurry. Next, an appropriate amount (for example: 0.5 wt % to 5 wt % relative to the particle weight) of silane coupling agent is added, and the pH value is adjusted to promote hydrolysis. Subsequently, the mixture is stirred and reacted at an appropriate temperature (such as: room temperature to 80° C.) for a certain time (such as: 1 hour to 4 hours) to allow the coupling agent to be fully grafted onto the particle surface. Finally, through filtration, washing and drying procedures (such as: drying at 100° C. to 120° C.), cleaning particles 122 with specific functional groups on the surface may be obtained.

In the aforementioned dry method, the raw material particles used to make cleaning particles 122 may first be placed in a high-speed mixer (such as: Henschel Mixer), and under high-speed stirring conditions, the silane coupling agent (or its diluted solution) is uniformly sprayed onto the particle surface by atomized spraying. Next, the mixture is heated to an appropriate temperature (such as: 80° C. to 130° C.) and maintained for a period of time to complete the surface condensation reaction. The dry method is suitable for mass production and does not require subsequent solvent removal steps.

When cleaning particles 122 are organic polymer particles, their formation method may be through direct preparation via monomer copolymerization. For example, suspension polymerization or emulsion polymerization methods may be adopted. During the polymerization process, in addition to the main structural monomers (such as: methyl methacrylate, styrene), monomers with functional groups are also added. For example, if it is desired to have carboxyl groups on the particle surface, acrylic acid or methacrylic acid may be added for copolymerization. For example, if it is desired to have alcohol groups, 2-hydroxyethyl methacrylate (HEMA) may be added. For example, if it is desired to have amide groups, acrylamide may be added. For example, if it is desired to have alkoxysilane groups, 3-methacryloxypropyltrimethoxysilane may be added as a copolymerization monomer. By controlling polymerization conditions and monomer ratios, organic cleaning particles 122 with particle sizes ranging from 0.05 micrometers to 30 micrometers and having specific reactive activity on the surface may be produced. Cleaning particles 122 with appropriate particle size ranges may be selected by appropriate methods (such as: using screens). The particle size of cleaning particles 122 may be selected according to the corresponding cleaning layer 120 thickness; for example: the maximum particle size of cleaning particles 122 is smaller than the cleaning layer 120 thickness; for example: the maximum particle size of cleaning particles 122 is smaller than or approximately equal to 20%, 10%, 1%, 0.5%, 0.1%, 0.05% or 0.02% of the cleaning layer 120 thickness.

Additionally, in terms of availability of commercially available materials, commercial products may be selected to meet implementation requirements. For example, the EPOSTAR series provided by Nippon Shokubai are crosslinked acrylate or melamine formaldehyde resin microparticles, whose surfaces may also have functional groups such as amino or carboxyl groups depending on the model. For example, the Micropearl series (such as SP-203, SP-204) microparticles produced by Sekisui Chemical may also be used.

### <Abrasive Particles>

Abrasive particles 123 (or may be called second particles, hard particles) are dispersed in resin 121 and mixed and coexist with cleaning particles 122. The main function of abrasive particles 123 is to utilize their higher hardness to perform physical grinding and cutting on the probe surface to remove contaminants (such as: metal oxides, adhered solder). Therefore, the hardness setting of abrasive particles 123 is significantly higher than cleaning particles 122. For example, the Mohs hardness of abrasive particles 123 is greater than or equal to 7.

The material type of abrasive particles 123 may be appropriately selected to provide sufficient cutting force. In an embodiment, the material of abrasive particles 123 is selected from at least one of the group consisting of aluminum oxide (Al₂O₃), silicon carbide (SiC), diamond, quartz, and titanium dioxide (TiO₂). Among these, aluminum oxide may be selected from single crystal aluminum oxide or polycrystalline aluminum oxide; silicon carbide may be selected from green silicon carbide or black silicon carbide. These high hardness materials may effectively destroy the structure of contaminants, causing them to peel off from the probe surface.

The morphology of abrasive particles 123 may be spherical or polygonal. Generally speaking, polygonal or sharp-angled abrasive particles 123 have stronger cutting ability, while spherical abrasive particles 123 could provide more uniform grinding effects. The particle size distribution of abrasive particles 123 may be between 0.02 micrometers and 50 micrometers. This particle size range has critical significance: if the particle size of abrasive particles 123 is less than 0.02 micrometers, the grinding efficiency is extremely low, making it difficult to remove thicker oxide layers; if the particle size of abrasive particles 123 is greater than 50 micrometers, it easily causes excessively deep scratches on the probe surface, or even damages the probe coating, shortening probe life.

In an embodiment, abrasive particles 123 may be selected from commercially available standard abrasive powders. For example, WA (white aluminum oxide) or GC (green silicon carbide) abrasive powders graded according to JIS R 6001 standard may be selected, with grit sizes corresponding to the aforementioned particle size range (for example #600 to #8000). In an embodiment, abrasive particles 123 may be prepared through sol-gel method or powder sintering and crushing method, and their particle size distribution may be controlled via screening or air classification techniques to ensure dispersion uniformity in resin 121 and consistency of cleaning performance.

### <Resin Material>

In an embodiment, resin 121 serving as the matrix or binder of cleaning layer 120 may have its chemical structure and physical properties appropriately selected to ensure that cleaning layer 120 could still maintain structural stability under harsh testing environments. For example, resin 121 is organic silicone resin. From a microstructural perspective, resin 121 may be polyorganosiloxane with a highly cross-linked network structure.

The backbone structure of resin 121 may be composed of silicon-oxygen bonds (Si—O bonds) formed by alternating connections of silicon atoms and oxygen atoms. The bond energy of these Si—O bonds is extremely high (approximately 444 kJ/mol), far higher than the carbon-carbon bonds (C—C bonds, approximately 356 kJ/mol) of general organic polymers, and may avoid the “carbonization contamination” problem under high-temperature testing environments. Therefore, resin 121 may have structural stability similar to inorganic materials (such as quartz, glass). This chemical structure endows resin 121 with excellent heat resistance, making it difficult to undergo thermal cracking, thermal oxidation, or free radical cleavage reactions in high-temperature environments. In an embodiment, resin 121 may operate stably for long periods within a wide temperature range of −50° C. to 250° C., and may withstand instantaneous high temperatures up to 300° C. or above for short periods. For example, if traditional carbon-based materials (such as epoxy resin or acrylic resin) are used, when probes conduct high-temperature testing (such as above 150° C.) or generate frictional heat due to continuous high-speed contact, these traditional resins easily undergo thermal cracking to produce carbon residue, which instead adheres to probes and becomes a difficult-to-remove contamination source. In an embodiment, this ensures that when decontamination material 100 is applied to high temperature probing, cleaning layer 120 is difficult or unlikely to undergo softening flow or brittle spalling.

The molecular weight characteristics of resin 121 may have an impact on the mechanical strength and processing rheological properties of the material. In an embodiment, the weight average molecular weight (Mw) of resin 121 may be between 30,000 and 800,000. If the molecular weight is below 30,000, the cured network structure may be too loose, resulting in insufficient cohesive strength; if the molecular weight is above 800,000, the resin viscosity may be too high, which may be unfavorable for subsequent mixing and dispersion with particles.

In an embodiment, the glass transition temperature (Tg) of resin 121 may be between-60° C. and −20° C. This low Tg characteristic endows resin 121 with good flexibility and rubber elasticity even in low-temperature environments, reducing or avoiding brittle fracture during cold tests.

In order to endow resin 121 with appropriate flexibility, processability, mechanical properties, and weather resistance, resin 121 is modified by introducing specific organic functional groups on the side chains of silicon atoms. The organic functional groups may include methyl (—CH₃), vinyl (—CH═CH₂), or phenyl (—C₆H₅).

In an embodiment, regarding the appropriate synthesis method of resin 121 and the means of introducing functional groups, appropriate silane monomers may be selected according to target characteristics to conduct hydrolysis and condensation reactions. Resin 121 may be formed by polymerization of various mixtures of monomers such as methyltrichlorosilane, dimethyldichlorosilane, phenyltrichlorosilane, diphenyldichlorosilane, or methylphenyldichlorosilane.

For example, if it is desired to introduce methyl (—CH₃) into the resin structure, methyltrichlorosilane or dimethyldichlorosilane may be selected as reaction monomers. The introduction of methyl may endow resin 121 with excellent water repellency and surface release properties. Since methyltrichlorosilane has three hydrolyzable chlorine groups, it may serve as cross-linking points in condensation reactions, helping to form a dense three-dimensional network structure (T units); while dimethyldichlorosilane may be applied to extend the length of molecular chains, providing flexibility to the material.

For example, if it is desired to introduce phenyl (—C₆H₅) into the resin structure, phenyltrichlorosilane, diphenyldichlorosilane, or methylphenyldichlorosilane may be selected. Phenyl has a larger volume (which may be called: steric hindrance), and its introduction may disrupt the regularity of polymer chains, thereby inhibiting crystallization, which helps maintain the flexibility of the material at extremely low temperatures. Additionally, the high resonance stability of phenyl may further enhance the heat resistance and antioxidant properties of resin 121. Generally speaking, the higher the phenyl content, the better the ablation resistance of the resin.

For example, if it is desired to introduce vinyl (—CH═CH₂) into the resin structure, monomers containing vinyl may be added during the polymerization process, such as vinyltrichlorosilane, methylvinyldichlorosilane, or dimethylvinylchlorosilane may be used for end-capping at the polymerization terminals. Vinyl is an appropriate reactive group for addition cure reactions. In subsequent curing processes, vinyl groups on side chains or terminals may undergo hydrosilylation reactions with cross-linking agents (such as: hydrogen-containing silicone oil) under the action of platinum catalysts, thereby causing resin 121 to transform from a liquid state to a solid elastomer.

In an embodiment, to meet mass production requirements and implementation convenience, resin 121 may optionally use commercially available two-component addition-type silicone rubber compositions. For example, Sylgard series (such as Sylgard 184) produced by Dow Chemical Company, KE series (such as KE-106, KE-1031) produced by Shin-Etsu Chemical Co., or RTV series products produced by Momentive Performance Materials may be selected. If commercial products are selected, the ratio may be further adjusted according to requirements, and/or the aforementioned monomers or modifiers may be additionally added to fine-tune the content of functional groups, thereby obtaining resin 121 that conforms to the characteristic range described in the present disclosure. For example, “Grafting via Reactive End-groups” or “Co-hydrolysis and Condensation” may be adopted for modification and preparation.

Taking the reactive end-group grafting method using commercial base resin modification as an example, functional group modification may be performed on commercial silicone resins that already have appropriate molecular weight (such as: polysiloxane fluids with terminal silanol (—SiOH) or silyl hydride (—SiH) groups).

For example: if it is desired to introduce vinyl or phenyl groups onto commercially available silanol-terminated polydimethylsiloxane (PDMS), condensation reactions may be utilized. One possible method is: dissolving commercially available silanol-terminated polydimethylsiloxane in an organic solvent (such as: toluene or xylene), and adding chlorosilane or alkoxysilane carrying the target functional groups as modifiers. For another example, if it is desired to introduce vinyl groups, dimethylvinylchlorosilane or vinyltrimethoxysilane may be added. For yet another example, if it is desired to introduce phenyl groups, methylphenyldichlorosilane or diphenyldimethoxysilane may be added.

In the presence of a catalyst (such as: dibutyltin dilaurate (DBTDL)) or acid acceptor (such as: pyridine), the reaction is conducted at 60° C. to 100° C. for 2 to 6 hours. The chloro or alkoxy groups on the modifier will react with the silanol groups at the resin terminals, eliminating hydrogen chloride or alcohol molecules, thereby bonding vinyl or phenyl groups to the terminals or side chains of the resin chain through chemical bonds (—Si—O—Si—).

Taking the monomer co-hydrolysis and condensation method using commercial base resin as an example, commercially available monomers with different functional groups may be directly used for copolymerization to appropriately adjust and control the ratio or distribution of methyl, phenyl, or vinyl groups in the resin molecular chain.

For example, if it is desired to introduce vinyl groups, commercially available vinyl monomers such as methylvinyldichlorosilane, vinyltrichlorosilane, or tetramethyltetravinylcyclotetrasiloxane may be used. Then, the aforementioned vinyl monomers are mixed with dimethyldichlorosilane (as chain extension monomer) and methyltrichlorosilane (as network crosslinking monomer) in predetermined molar ratios, and dropped into a reaction vessel containing water, organic solvent (such as: toluene), and isopropanol. The temperature is controlled below 50° C. to conduct hydrolysis reaction to obtain silanol, then the temperature is raised to reflux temperature (such as: 100° C.-110° C.) to conduct dehydration condensation reaction (Bodying step). By adjusting the addition amount of vinyl monomers (for example: 0.5% to 5% of the total monomer molar amount), the vinyl content in resin 121 may be controlled, thereby determining the crosslinking density and hardness after curing.

For example, if it is desired to introduce phenyl groups, commercially available phenyl monomers such as phenyltrichlorosilane (PhSiCl₃), diphenyldichlorosilane (Ph₂SiCl₂), or methylphenyldichlorosilane (MePhSiCl₂) may be used. Then, the phenyl monomers are co-hydrolyzed with methyl monomers. Since the hydrolysis rate of phenyl monomers is slower than that of methyl monomers, in order to reduce uneven component distribution (such as: formation of homopolymers), it may be necessary to use “dropwise addition method” or use co-solvents (such as: acetone) to control the hydrolysis rate.

For example, if it is desired to introduce methyl groups, commercially available methyl monomers such as dimethyldichlorosilane, hexamethyldisiloxane, or trimethylchlorosilane may be used. Methyl monomers may serve as “end-capping” modification to enable resin 121 to have an appropriate molecular weight range. For example, the addition of methyl monomers may cause chain segments to stop growing. Thereby, the molecular weight of the resin may be adjusted within a preset range, or have an appropriate functional group ratio.

It is worth noting that the cleaning layer 120 of the embodiment of the present disclosure uses an appropriate ratio of cleaning particles 122 (Mohs hardness <7) and abrasive particles 123 (Mohs hardness ≥7) dispersed in resin 121 having an appropriate elastic modulus (40 kg/cm² to 200 kg/cm²). This configuration produces an unexpected stress dispersion mechanism at the microscopic mechanical level. For example, if only high hardness particles are used, when the probe penetrates at high speed, the particle-resin interface is extremely prone to microcracks due to stress concentration, causing particle fall-out. In an embodiment, the cleaning particles 122 (Mohs <7) and the abrasive particles 123 (Mohs ≥7) act synergistically. For example, the cleaning particles 122 unexpectedly function as “micro-dampers” around the abrasive particles 123. This synergistic configuration effectively mitigates secondary contamination while maintaining high cutting force. For example, when the probe impacts the abrasive particles 123, the instantaneous impact force generated may be absorbed and buffered by the surrounding softer cleaning particles 122. In other words, the presence of cleaning particles 122 is not only for adsorbing contaminants (such as: substance 99 described later), but also mechanically stabilizes the anchoring effect of the abrasive particles 123. In this way, the cleaning layer 120 provides sufficient cutting force to remove contaminants while significantly reducing the wear rate of the probe tip and effectively suppressing secondary contamination caused by material brittleness. Therefore, the decontamination material 100 of the embodiment of the present disclosure may still maintain extremely high process yield rate and statistical robustness under long-term continuous testing (such as: up to 1500 times).

### <Additives for Cleaning Layer>

In an embodiment, in order to optimize the processability of the cleaning layer 120, the surface flatness after film formation, or to adjust the chemical reaction rate, in addition to the aforementioned resin 121, cleaning particles 122, and abrasive particles 123, various functional additives may also be added to the composition of the cleaning layer 120. The additives may be selectively added or added corresponding to the reaction mechanism. The types and amounts of the additives may be appropriately selected according to the actual formulation design.

In an embodiment, in order to promote resin 121 to form the aforementioned highly cross-linked network structure, the raw material composition of the cleaning layer 120 may include a cross-linking agent. The type of cross-linking agent is appropriately selected according to the reaction mechanism of resin 121. When resin 121 uses polyorganosiloxane containing vinyl groups (e.g., addition-type silicone resin system), the cross-linking agent may use organohydrogenpolysiloxane containing silicone hydride groups (Si—H). In this system, the cross-linking agent utilizes its silicone hydride groups to undergo hydrosilylation reaction with the vinyl groups of resin 121, thereby forming a three-dimensional network structure. In order to ensure sufficient curing and no excessive residual reactive groups, the addition amount of cross-linking agent may be appropriately selected, for example, making the molar ratio of silicone hydride groups to vinyl groups (H/Vi ratio) between 0.8 to 3.0. Common commercially available cross-linking agents include, for example, Shin-Etsu Chemical's X-92 series or Dow's Syl-Off series cross-linking agents.

In an embodiment, if resin 121 uses polydimethylsiloxane without unsaturated bonds (e.g., peroxide-type silicone resin system), the cross-linking agent may use organic peroxide, for example benzoyl peroxide (BPO) or 2,4-dichlorobenzoyl peroxide. In an embodiment, if considering the high cleanliness requirements of semiconductor testing in applications, in order to reduce or avoid the release of reaction by-products, using the aforementioned addition-type system (hydrosilylation) may be more suitable.

In an embodiment, in order to initiate or accelerate the aforementioned cross-linking reaction, a catalyst may be added to the cleaning layer 120. For addition-type silicone resin systems, the catalyst is usually selected from platinum-based catalysts, for example chloroplatinic acid, Karstedt's catalyst, or platinum-vinylsiloxane complex. The content of the catalyst is usually extremely low, for example, calculated by the weight of metallic platinum, approximately 1 ppm to 100 ppm of the total resin weight.

In an embodiment, in order to enhance the flatness of the surface of cleaning layer 120, thereby further optimizing decontamination material 100's total thickness variation (TTV), a leveling agent may be added to cleaning layer 120. The types of leveling agents may include modified polysiloxane, fluorinated surfactants, or acrylic copolymers. In an embodiment, based on the total weight of resin 121, the content of leveling agent may be between 0.05 wt % to 3 wt %. If the leveling agent content is too low, it may not effectively eliminate orange peel or crater phenomena during coating; if the content is too high, it may affect interlayer adhesion or contaminate the probe.

In an embodiment, in order to ensure uniform dispersion of cleaning particles 122 and abrasive particles 123 in resin 121, avoiding particle agglomeration, a dispersant may be added to cleaning layer 120. At the same time, in order to eliminate bubbles generated during stirring or coating processes, a defoamer may also be added. In the coating process, in order to adjust viscosity to an appropriate coating range, a solvent may also be added, such as toluene, xylene, heptane, or methyl ethyl ketone (MEK), wherein the solvent will be volatilized and removed in the subsequent drying process.

### <Formation Method and Reaction Condition Control of Cleaning Layer>

Regarding the preparation of cleaning layer 120, first the aforementioned resin 121, cleaning particles 122, and abrasive particles 123; or, further including other optional additives (e.g., cross-linking agent, catalyst, leveling agent, etc.; but not limited) are mixed according to predetermined ratios, and dispersed through a stirring device to form a uniform coating solution. Next, the coating solution is coated on the surface of support layer 110, and a heating curing procedure is conducted to cause resin 121 to undergo cross-linking reaction and form solid cleaning layer 120.

In an embodiment, the curing reaction conditions of cleaning layer 120 (e.g., reaction temperature and reaction time) may be appropriately selected to control the final physical properties of cleaning layer 120. For example, the reaction temperature (herein designated as “temperature A”) and reaction time (herein designated as “time B”) are not merely process parameters, but are key factors determining the formation of polymer network structure.

From the perspective of chemical reaction kinetics or thermodynamics, even when using completely identical reactants e.g., same resin formulation and particle ratio), if different reaction conditions are applied, it may also cause the product e.g., cleaning layer 120) to have distinctly different microstructure and macroscopic properties. This is because chemical reactions typically involve a plurality of competing pathways, and each pathway has different activation energy (Activation Energy, Ea) and reaction energy barriers.

For example, assuming that during the curing process of resin 121, there exist two competing reaction pathways or mechanisms: the first reaction pathway has a higher reaction energy barrier, and its generated product structure or cross-linking mode is defined as “Product X”; the second reaction pathway has a lower reaction energy barrier, and its generated product structure or cross-linking mode is defined as “Product Y”. According to the Arrhenius equation, the reaction rate constant has an exponential relationship with temperature. If the reaction temperature is set lower (for example: “temperature A”−20° C.), although the total thermal energy provided by the system is lower, it is sufficient to overcome the low energy barrier of the second reaction pathway, but difficult to overcome the high energy barrier of the first reaction pathway. In this case, if simultaneously combined with a longer reaction time (for example: “time B”+20 minutes) to ensure reaction completion, then in the final cured product, the concentration or ratio of “Product Y” (low energy barrier pathway product) will be relatively higher. Conversely, if the reaction temperature is set higher, then the system has sufficient energy to overcome the high energy barrier, and the generation ratio of “Product X” may increase accordingly.

In the cross-linking reaction of organosilicon resin, the aforementioned “Product X” and “Product Y” may correspond to different cross-linking point distributions, side chain reactions, or molecular chain arrangement orderliness. Different microstructures will directly endow cleaning layer 120 with different mechanical properties. Therefore, the technical feature of the formation method of the cleaning layer of the present disclosure may lie in: by controlling appropriate reaction temperature and time, guiding the chemical reaction toward the desired pathway (for example: promoting most reactants to undergo specific reactions of low energy barrier or high energy barrier), thereby enabling the generated cleaning layer 120 to possess appropriate and expected physical characteristics.

Furthermore, in polymer reaction control, the duration of time also plays a key role. Curing time and curing temperature typically exhibit a complementary relationship, but their effects on polymer chain movement and free volume are not entirely the same.

In an embodiment, if a “low temperature with long time” curing strategy is selected (for example: reducing curing temperature and extending curing time), the reaction rate will decrease accordingly. Under a slower reaction rate, polymer chain segments have more sufficient time for stretching and arrangement, and before cross-linking points are formed, the diffusion of molecular chains is less hindered. This mild reaction process tends to form a more uniform network structure with lower internal stress and fewer defects. Such structural differences will be reflected in macroscopic physical properties, for example, the hardness or elastic modulus of the material may decrease accordingly, exhibiting better flexibility and ductility.

Conversely, if a “high temperature with short time” curing strategy is selected, the reaction rate is extremely fast, and polymer chains may be “locked-in” by cross-linking points before they are fully stretched, resulting in more microscopic defects or higher residual internal stress in the network structure. Although this method has high production efficiency, it may cause the material to exhibit higher rigidity or more brittle properties.

Based on the aforementioned principles, in order to obtain the characteristics suitable for probe cleaning as described in the present disclosure, the curing temperature of cleaning layer 120 may be appropriately selected, for example between 80° C. to 160° C., or for example between 110° C. to 150° C.; the curing time may also be appropriately selected, for example between 5 minutes to 90 minutes, or for example between 10 minutes to 60 minutes. By making appropriate parameter adjustments within the aforementioned ranges, the cross-linking density of resin 121 may be optimized, thereby enabling the overall characteristics of cleaning layer 120 (such as: hardness, modulus, recovery force, etc.) to reach the optimal balance point required for probe cleaning processes.

### <Physical Properties and Control of Cleaning Layer>

To overcome the deficiencies of conventional approaches, the macroscopic physical properties (e.g., hardness and elastic modulus) of the cleaning layer 120 are strictly controlled. This ensures that the cleaning layer 120 can effectively clean the probes while simultaneously preserving the probes, and reducing or preventing the disintegration of the decontamination material itself.

For the hardness of cleaning layer 120, the hardness of cleaning layer 120 is defined by Shore A hardness. In an embodiment, the Shore A hardness value of cleaning layer 120 may be between 40 to 90. The setting of this hardness range is not arbitrary selection, but has its technical critical significance. For example, if the Shore A hardness of cleaning layer 120 is less than 40, it typically means that the cross-linking degree of resin 121 may be relatively low, with the material being too soft and having a loose structure. In this state, the elastic recovery of cleaning layer 120 after being compressed by probes is too poor, resulting in inability to provide sufficient friction force to remove contaminants, thereby reducing cleaning capability. Conversely, if the Shore A hardness of cleaning layer 120 is between 90 to 100, it means that the cross-linking degree of resin 121 may be too high, with material properties being too rigid and brittle. When probe cleaning is performed in this state, cleaning layer 120 is extremely prone to microscopic cracking due to stress concentration, generating debris or dusting, which not only reduces cleaning capability but also causes serious secondary pollution.

In an embodiment, the hardness value of cleaning layer 120 may be measured according to international standards or Japanese Industrial Standards (JIS). For example, it may be obtained by testing the cured cleaning layer 120 using a Type A Durometer according to ASTM D2240 or JIS K 6253 standards.

The hardness of cleaning layer 120 may be controlled through various factors such as molecular structure or cross-linking density.

Taking molecular structure as an example, the molecular chain structure of resin 121 may affect its microscopic rigidity. If the molecular structure of resin 121 contains more long straight carbon chains, the resin exhibits softer properties; if aromatic hydrocarbons (such as phenyl) or structures with greater steric hindrance are introduced into the molecular structure, the molecular chain rigidity increases and the resin exhibits more rigid properties.

Taking cross-linking density as an example, cross-linking density is proportional to the cohesion of the material. Low cross-linking density results in low cohesion; high cross-linking density results in high cohesion. In order to control appropriate cross-linking density, the weight percentage of cross-linking agent added to resin 121 may be appropriately selected. In an embodiment, based on the total weight of resin 121, the content of cross-linking agent may be between 10 wt % to 60 wt %. If the cross-linking agent content is less than 10 wt %, the cross-linking density is too low and hardness is insufficient, resulting in poor recovery; if the cross-linking agent content is greater than 60 wt %, the cross-linking density is too high and hardness is excessive, easily leading to risks of debris generation and secondary contamination.

For the elastic modulus of cleaning layer 120, the elastic modulus (or Young's modulus) of cleaning layer 120 represents the ability of the material to resist deformation (rigidity). In an embodiment, the elastic modulus of cleaning layer 120 may be between 40 kg/cm² to 200 kg/cm². This range also has critical technical significance: if the elastic modulus is less than 40 kg/cm², the material is too easily deformed and has insufficient recovery force (poor recovery), and the probe cannot obtain sufficient reaction force to scrape off contaminants after penetration, thereby reducing cleaning capability. If the elastic modulus is greater than 200 kg/cm², the material rigidity is too strong and not easily deformed. When the probe penetrates at high speed, cleaning layer 120 cannot disperse stress through elastic deformation, resulting in surface fragmentation and debris generation, causing secondary contamination. If the elastic modulus of the cleaning layer 120 is appropriately controlled between 40 kg/cm² and 200 kg/cm², the cleaning layer 120 could achieve an optimal balance between structural integrity and cleaning efficacy, for example, a balance between “effective probe cleaning” and “reducing or avoiding material damage”, successfully reducing or preventing the micro-cracking issue prevalent in conventional materials.

In an embodiment, the elastic modulus value of cleaning layer 120 may be measured according to standard tensile test methods. For example, according to ASTM D412 or JIS K 6251 standards, dumbbell-shaped test specimens may be prepared and tensile testing conducted, with the elastic modulus calculated from the slope of the linear region of the stress-strain curve.

The elastic modulus of cleaning layer 120 may be controlled through various factors such as molecular weight, glass transition temperature (Tg), or filler loading.

Taking molecular weight as an example: the molecular weight of resin 121 may be selected between 30,000 to 800,000. Generally speaking, resins with lower molecular weight are unfavorable for intermolecular entanglement and cohesion, resulting in lower elastic modulus; resins with higher molecular weight are favorable for enhancing cohesion, resulting in higher elastic modulus.

Taking glass transition temperature as an example: the glass transition temperature of resin 121 may be selected between −60° C. to −20° C. Lower glass transition temperature usually corresponds to poorer cohesion and lower elastic modulus, with relatively lower temperature resistance; higher glass transition temperature corresponds to better cohesion and higher elastic modulus, with better temperature resistance. By adjusting the ratio of copolymer monomers (such as phenyl content), the glass transition temperature may be correspondingly controlled to achieve the target elastic modulus.

Taking particle filling ratio as an example: the addition amount of solid components (e.g., cleaning particles 122 and abrasive particles 123) dispersed in resin 121 is also critical. Based on the weight of resin 121, the weight percentage of solid components (e.g., cleaning particles 122 and abrasive particles 123) added may be between 10% to 100%. Since the rigidity of particles may be higher than the resin matrix, by adding different types of particles or changing the addition ratio of solid components, the overall elastic modulus of the composite material may be effectively adjusted. For example, increasing particle content usually enhances the overall elastic modulus.

In an embodiment, the curing temperature of cleaning layer 120 is between 130° C. to 150° C. (such as: approximately 140° C.; i.e., 140° C.±5%), and the curing time may be between 10 minutes to 30 minutes (such as: approximately 20 minutes; i.e., 20 minutes±5%). Moreover, through the aforementioned corresponding curing temperature and curing time, the Shore A hardness of cleaning layer 120 may be between 50 to 80 (such as: approximately 60 A; i.e., 60 A±5%), and/or the elastic modulus of cleaning layer 120 may be between 70 kg/cm² to 150 kg/cm² (such as: approximately 100 kg/cm²; i.e., 100 kg/cm²±5%).

In an embodiment, the curing temperature of cleaning layer 120 is between 100° C. to 130° C. (such as: approximately 120° C.; i.e., 120° C.±5%), and the curing time may be between 30 minutes to 60 minutes (such as: approximately 40 minutes; i.e., 40 minutes±5%). Moreover, through the aforementioned corresponding curing temperature and curing time, the Shore A hardness of cleaning layer 120 may be between 40 to 50 (such as: approximately 40 A; i.e., 40 A±5%), and/or the elastic modulus of cleaning layer 120 may be between 40 kg/cm² to 70 kg/cm² (such as: approximately 40 kg/cm²; i.e., 40 kg/cm²±5%).

### <Usage Method of Decontamination Material>

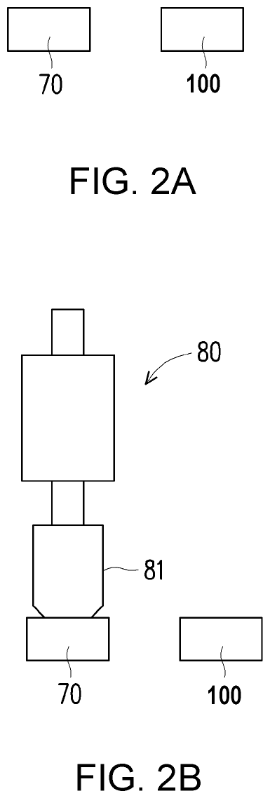

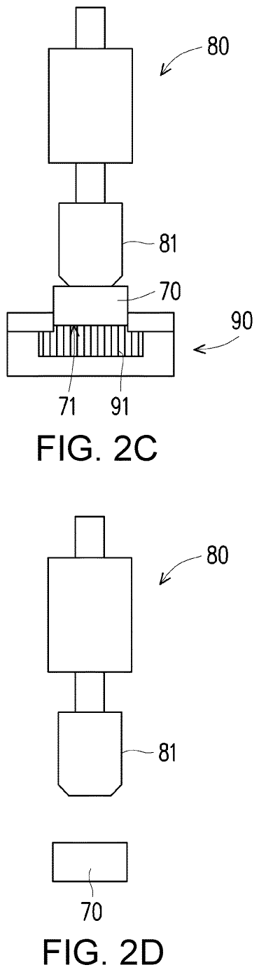

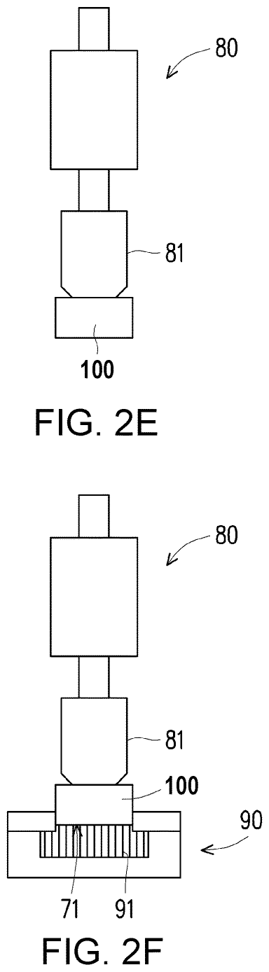

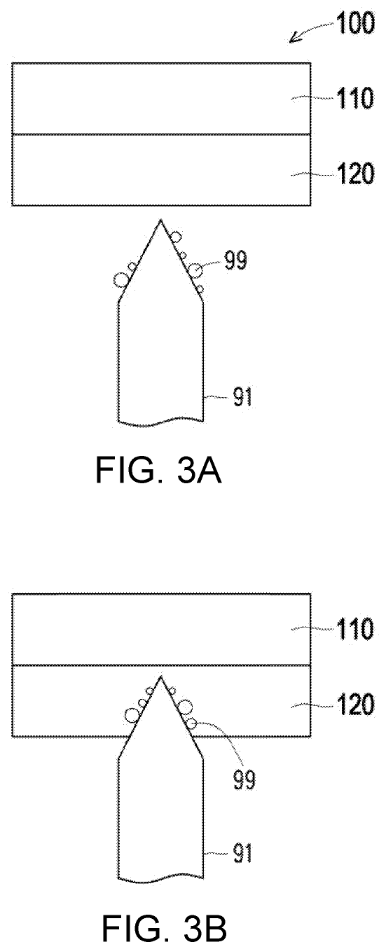

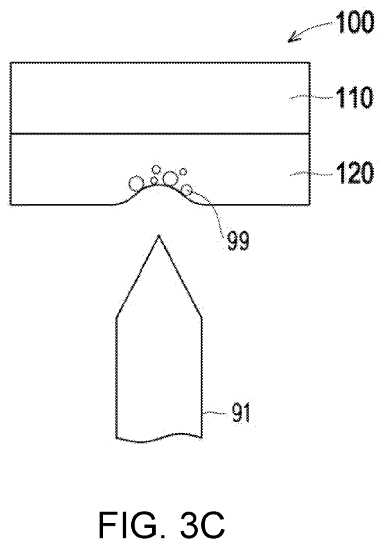

FIG. 2A to FIG. 2F are schematic views illustrating a usage method of a decontamination material (or: a probe cleaning method) according to an embodiment of the present disclosure. Additionally, for clarity or brevity, in FIG. 2A to FIG. 3C, decontamination material 100 is only schematically illustrated, and the support layer 110, cleaning layer 120, cleaning particles 122 and abrasive particles 123 in cleaning layer 120 may be omitted from illustration.

Referring to FIG. 2A to FIG. 2C, electrical testing may be performed on electronic components 70 by probe 91 through commonly used testing methods.

Taking FIG. 2A as an example, electronic components 70 and decontamination material 100 (including support layer 110 and cleaning layer 120) are provided.

In an embodiment, electronic components 70 are, for example, bare die or chip package, but the present disclosure is not limited thereto.

Then, as shown in FIG. 2B, the electronic components 70 to be tested may be picked up by pick and place head 81 of pick and place device 80.

Then, as shown in FIG. 2C, the electronic components 70 to be tested may be placed on test device 90 by pick and place device 80.

Test device 90 has, for example, one or more probe pins 91. Probe 91 may contact conductive terminals (such as: solder balls) (not shown) or contact pads (not shown) on test surface 71 of electronic components 70 to test electronic components 70. For example, pressure may be applied to electronic components 70 to be tested and/or probe 91, so that the conductive terminals or contact pads on test surface 71 of electronic components 70 to be tested contact probe 91.

In an embodiment, the testing method is, for example, final test (FT), but the present disclosure is not limited thereto. In an embodiment, the testing method may be chip probing (CP).

After the exemplary testing in the aforementioned FIG. 2A to FIG. 2C, probe 91 may be cleaned by decontamination material 100 through similar operation methods.

Taking FIG. 2C to FIG. 2D as an example, after testing electronic components 70, electronic components 70 and probe 91 may be separated, and electronic components 70 may be placed by pick and place device 80.

In an embodiment, during the process of electronic components 70 contacting and/or separating from probe 91, partial substances on electronic components 70 (such as: solder forming conductive terminals or aluminum, zinc or copper materials forming contact pads) may peel off and adhere to probe 91.

Then, as shown in FIG. 2E, decontamination material 100 may be picked up by pick and place head 81 of pick and place device 80.

Then, as shown in FIG. 2F, decontamination material 100 may be placed on test device 90 by pick and place device 80 to clean probe 91 by decontamination material 100.

For example, pressure may be applied to decontamination material 100 and/or probe 91 to bring decontamination material 100 into contact with probe 91, so that substance 99 adhered to probe 91 (such as: solder, aluminum, zinc, copper or possible stains; labeled or shown in FIG. 3A to FIG. 3C) is adhered by cleaning layer 120 of decontamination material 100. Thereafter, decontamination material 100 and probe 91 may be separated, and substance 99 adhered to probe 91 may be reduced by decontamination material 100.

In detail, Referring to FIG. 3A to FIG. 3C.

As shown in FIG. 3A to FIG. 3B, one end of probe 91 used for testing (e.g., one end for contacting electronic components 70) may penetrate into cleaning layer 120 of decontamination material 100. Substance 99 attached to probe 91 may be loosened from probe 91 by abrasive particles (e.g., the aforementioned abrasive particles 123) in cleaning layer 120. For example, during the process of probe 91 penetrating into cleaning layer 120, substance 99 on probe 91 may rub against abrasive particles in cleaning layer 120. Moreover, since substance 99 originally attached to probe 91 may have already been loosened from probe 91, cleaning particles (e.g., the aforementioned cleaning particles 122) in cleaning layer 120 may more easily remove substance 99 from probe 91.

As shown in FIG. 3C, during the process of probe 91 separating from cleaning layer 120, the silicone resin and the cleaning particles actively trap and encapsulate a large portion of the substance 99 detached from the probe 91, for example, substance 99 removed from probe 91 may be embedded or trapped in silicone resin, thereby physically reducing or preventing the substance 99 from re-adhering to the probe tip. In an embodiment, in a unit volume, since the number of cleaning particles in cleaning layer 120 is greater than the number of abrasive particles, in this way, a large portion of substance 99 removed from probe 91 may be more easily embedded or trapped in silicone resin by cleaning particles, and/or the possibility of removed substance 99 separating from decontamination material 100 due to withdrawal of probe 91 during the process of probe 91 separating from decontamination material 100 into which it penetrated may be reduced. Therefore, decontamination material 100 may have more effective uses. Moreover, after separating decontamination material 100 from probe 91, the amount of substance 99 adhered to and/or coated on probe 91 may be reduced.

In an embodiment, even during the process of probe 91 contacting and/or separating from cleaning layer 120, abrasive particles may produce corresponding scratches on probe 91 (but with the possibility of “no scratch” or “scratch-free”), but since the particle size of abrasive particles is approximately 0.02 micrometers to 50 micrometers, the size and/or traces of scratches (if any) may also be reduced, and the possibility of probe 91 having reduced performance in subsequent use due to scratches (if any) may be reduced.

In the method or steps of cleaning probe 91 using decontamination material 100 of any of the aforementioned embodiments of the present disclosure, probe 91 may not be disassembled or separated from test device 90. Moreover, cleaning of probe 91 may be performed using the same or similar operating parameters (recipe) as those for testing electronic components 70. That is, the steps of the probe 91 cleaning method may be performed in-situ or on-line.

It is worth noting that FIG. 2A to FIG. 3C merely exemplarily introduce a cleaning method for probe 91, and the present disclosure does not limit the type of probe 91. For example, in FIG. 2A to FIG. 3C, the illustrated probe 91 is a vertical probe pin, but the present disclosure is not limited thereto. In an embodiment not illustrated, decontamination material 100 of any of the aforementioned embodiments of the present disclosure may also be used for cleaning cantilever probe pins through a method similar to general testing methods.

### EXAMPLES

The present disclosure is specifically described by the following examples (including: all experimental examples and comparative examples). Embodiments of the present disclosure may include the following experimental examples, but embodiments of the present disclosure are not limited to the following experimental examples.

Among the various examples, the main differences lie in the relative conditional relationships (e.g., variables) described in each experiment. Therefore, except for the specific variable, other conditions constituting the decontamination material, such as the type of resin material, the types, ratios and particle size distributions of abrasive particles and cleaning particles, the material and thickness of support layer, the total thickness of support layer and cleaning layer, etc., are maintained substantially the same or similar to effectively observe the effect differences brought about by the specific variable. The specific formulations and test results described below are used to illustrate the technical principles and efficacy of the present disclosure, and are not intended to constitute any limitation on the scope of the present disclosure.

### <Cleaning Effect Test>

To evaluate the cleaning efficiency of samples in each example, the actual testing process of assembly and test facilities was simulated. The test conditions were set such that after testing the same 50 integrated circuit chips (IC), 10 cleaning cycles of needle poking were performed on the decontamination material samples, and this testing and cleaning process was continued until a total of 1500 cleanings were cumulatively completed on the samples. Crown head probes were used throughout the test, and effectiveness was evaluated using two key indicators of online electrical testing: Yield Rate and Open/Short Rate (O/S Rate).

Yield rate is a core indicator in semiconductor manufacturing, defined as: the percentage of ICs that pass electrical testing and are determined to be functionally normal out of the total number of ICs. Probe testing is a critical step in determining this initial yield rate, and its accuracy is crucial. If probes are contaminated due to inadequate cleaning, it may cause unstable contact resistance, leading to the misjudgment of functionally normal ICs as defective products, resulting in yield loss. Therefore, whether decontamination material could continuously help cleaned probes maintain high and stable yield rates during long-term testing is an important criterion for evaluating its cleaning effectiveness.

### [Experimental Example 1] and [Experimental Example 2]

The fabrication and testing of [Experimental Example 1] and [Experimental Example 2] are to further verify the characteristic changes of the decontamination material of the present disclosure (such as: decontamination material 100) under different process conditions and their impact on cleaning effectiveness. The fabrication methods of [Experimental Example 1] and [Experimental Example 2] both fall within the process range disclosed in the aforementioned embodiments, namely: curing temperature between approximately 80° C. to 160° C., and curing time between approximately 5 minutes to 90 minutes. Specifically, the main difference between [Experimental Example 1] and [Experimental Example 2] lies in the control of curing kinetic conditions. The curing temperature setting of [Experimental Example 2] is 20° C. lower than that of [Experimental Example 1], while the curing time setting of [Experimental Example 2] is 20 minutes longer than that of [Experimental Example 1]. This experimental design aims to explore the effects of two curing strategies: “low temperature with long time” and “high temperature with short time” (relatively speaking) on the resin crosslinking network structure and final physical properties. The results of [Experimental Example 1] and [Experimental Example 2] are shown in [Table 1].

TABLE 1

| | Experimental | Experimental |
|---|---|---|
| | Example 1 | Example 2 |
| curing | 140 | 120 |
| temperature (° C.) | | |
| curing time (min) | 20 | 40 |
| hardness (Shore A) | 60 | 40 |
| elastic modulus (kg/cm²) | 100 | 40 |
| yield | 95.3 | 94.6 |

Through measurement, it could be known that the cleaning layer of [Experimental Example 1] has a hardness of Shore A 60 and an elastic modulus of 100 kg/cm²; while the cleaning layer of [Experimental Example 2] has a hardness of Shore A 40 and an elastic modulus of 40 kg/cm². From the perspective of polymer chemical reaction kinetics, under the same formulation composition, reducing the curing temperature will significantly decrease the reaction rate constant, allowing the resin molecular chains to have longer relaxation time before crosslinking points are formed, resulting in the final network structure having lower crosslinking density or more free volume, thereby causing the macroscopic hardness and elastic modulus to decrease accordingly. This result confirms that the present disclosure may precisely control the mechanical properties of the cleaning layer through fine-tuning of curing conditions to adapt to the cleaning requirements of different probe types.

Furthermore, actual probe cleaning tests were conducted for [Experimental Example 1] and [Experimental Example 2], and their yield rates were statistically analyzed. The results show that [Experimental Example 1] has a yield rate of 95.3%, while [Experimental Example 2] has a Yield Rate of 94.6%. The data indicates that even under conditions where physical properties (hardness 40 to 60, elastic modulus 40 to 100 kg/cm²) differ, by controlling process conditions within appropriate temperature (80° C. to 160° C.) and appropriate reaction time (5 minutes to 90 minutes) ranges, particularly as shown in [Experimental Example 2] by extending curing time to compensate for the reaction rate decrease caused by low temperature, the product yield rate may still reach a process capability level above 3 standard deviations (3 Sigma, approximately 93.3%). This shows that the decontamination material of the present disclosure has high process stability and a broad process window. Additionally, under continuous high-intensity testing, the decontamination material may still maintain a high yield rate above 94%, demonstrating its excellent statistical robustness, effectively suppressing outliers caused by contamination accumulation or operational variations, ensuring reliability in semiconductor mass production testing.

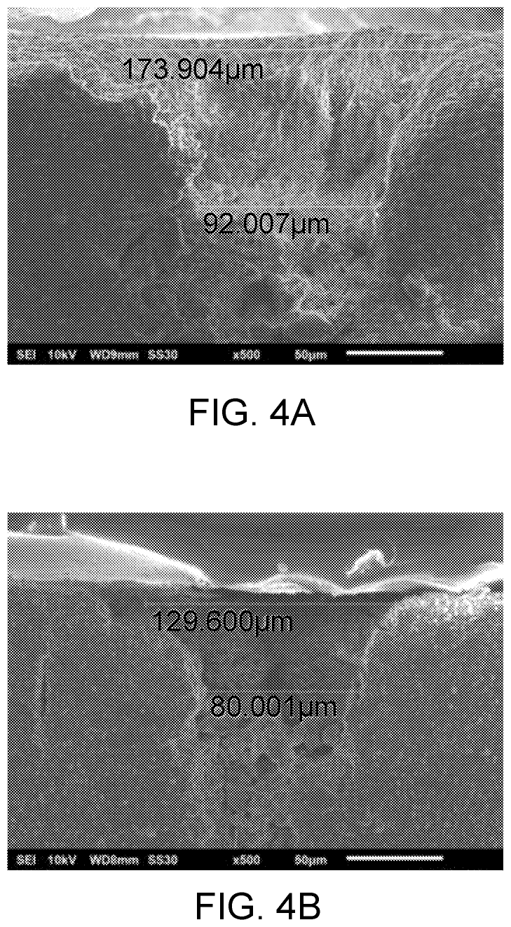

FIG. 4A is a partial cross-sectional enlarged view of a cleaning layer according to a comparative example. FIG. 4B is a partial cross-sectional enlarged view of a cleaning layer according to an experimental example ([Experimental Example 2]) of the present disclosure. Specifically, FIG. 4A and FIG. 4B are respectively the cleaning layers corresponding to the comparative example and experimental example, after cumulative completion of a total of 1500 cleanings, their needle puncture areas are enlarged views observed at 500× magnification through a Scanning Electron Microscope (SEM).

Following the above analysis, the fabrication and testing of [Experimental Example 2] and [Comparative Example] were conducted to clarify the key influence of process parameters (curing temperature and time) on material microstructure and final cleaning performance. The fabrication method of [Experimental Example 2] adopts a relatively low curing temperature (20° C. lower than [Experimental Example 1]) combined with a relatively long curing time (20 minutes longer than [Experimental Example 1]). This “low temperature with long time” process strategy aims to promote sufficient extension and uniform crosslinking of polymer chains. In contrast, [Comparative Example] adjusts process parameters by adopting the same high curing temperature as [Experimental Example 1], but by significantly shortening the curing time (i.e., “high temperature with short time” or “high temperature abrupt stop”), artificially controlling its reaction conversion rate to reduce its final elastic modulus to a value similar to [Experimental Example 2] (i.e., both have elastic modulus of approximately 40 kg/cm²). The purpose of this experimental design is to demonstrate that simple physical parameter (such as elastic modulus) values are not the sole factor determining cleaning performance; the network quality of the material's internal structure may also be key.

Through actual probe cleaning tests and yield statistics, the results show that [Experimental Example 2] with an elastic modulus of approximately 40 kg/cm² achieves a high-level yield of 94.6%; however, [Comparative Example] with the same elastic modulus of approximately 40 kg/cm² shows a significant drop in yield to 82.4%. The data indicates that [Comparative Example] experienced significant degradation in performance, with severely insufficient process capability of the decontamination material. This low yield level cannot meet the basic requirements for process stability in the semiconductor assembly and test industry, indicating that contaminants on the probe tip were not effectively removed, or the cleaning layer itself caused secondary contamination due to structural instability. This unstable cleaning effect directly leads to enormous random variation in contact resistance (Cres) during the testing process, which may very likely cause the overall testing process to be in an out of control state.

From the perspective of polymer physics and chemical reaction engineering, although [Comparative Example] and [Experimental Example 2] exhibit similar rigidity (elastic modulus) macroscopically, as shown in FIG. 4A and FIG. 4B, their microstructures are completely different. [Experimental Example 2], through a “low temperature, long time” curing process, provides sufficient thermal motion time for resin molecular chains to undergo conformational rearrangement and stress release, forming a homogeneous cross-linked network with fewer defects. This structure endows the material with “true elasticity” and excellent cohesive strength, enabling it to exhibit stable recovery when subjected to repeated compression. In contrast, [Comparative Example] forcibly terminates the reaction under “high temperature, short time” conditions to obtain low modulus, which may result in a large number of dangling chains, unreacted low molecular weight species (sol fraction), or regions with extremely uneven cross-linking density distribution within the resin. This “pseudo-softness” caused by incomplete reaction or kinetic trapping, although yielding lower measured modulus, fundamentally lacks sufficient structural strength and toughness. When the probe penetrates, the structure of [Comparative Example] easily undergoes irreversible plastic deformation or microscopic collapse, and may even transfer unreacted low molecular substances to the probe surface, causing contact resistance to surge. Therefore, to ensure that the decontamination material possesses reliable cleaning performance, in addition to controlling physical properties within appropriate ranges, the temperature (80° C. to 160° C.) and time (5 minutes to 90 minutes) of the curing process may also be appropriately selected and matched to ensure the formation of high-quality cross-linked network structure.

### UTILITY OR INDUSTRIAL APPLICABILITY

A method for manufacturing decontamination material according to an embodiment of the present disclosure is suitable for manufacturing decontamination material. The decontamination material is suitable for cleaning probes or removing stains on probes.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A decontamination material, comprising:
a support layer; and
a cleaning layer disposed on the support layer, wherein the cleaning layer comprises a resin, a plurality of cleaning particles dispersed in the resin, and a plurality of abrasive particles dispersed in the resin,
wherein the cleaning particles have a Mohs hardness of less than 7, and the abrasive particles have a Mohs hardness greater than or equal to 7.

2. The decontamination material according to claim 1, wherein the cleaning layer has a Shore hardness A between 40 and 90, and the cleaning layer has an elastic modulus between 40 kg/cm2 and 200 kg/cm2.

3. The decontamination material according to claim 1, wherein the resin is an organosilicon resin, the organosilicon resin has a highly cross-linked network structure, and the organosilicon resin has a weight average molecular weight between 30,000 and 800,000, and the organosilicon resin has a glass transition temperature between −60° C. and −20° C.

4. The decontamination material according to claim 1, wherein the material of the cleaning particles comprises organic polymer material or glass, and the surface of the cleaning particles has at least one functional group selected from the group consisting of alkenyl, ether, amide, amino, carboxyl, ester, alcohol, silane, alkoxy, and alkoxysilane groups.

5. The decontamination material according to claim 1, wherein the material of the abrasive particles is selected from at least one of the group consisting of aluminum oxide, silicon carbide, diamond, quartz, and titanium dioxide, and the abrasive particles have a spherical or polygonal shape.

6. The decontamination material according to claim 1, wherein the thickness of the cleaning layer is between 10 micrometers and 400 micrometers, and the thickness of the support layer is between 50 micrometers and 8000 micrometers.

7. A method for manufacturing a decontamination material, comprising:
providing a support layer;
mixing a resin, a plurality of cleaning particles, and a plurality of abrasive particles to form a coating solution, wherein the cleaning particles have a Mohs hardness of less than 7, and the abrasive particles have a Mohs hardness greater than or equal to 7;
coating the coating solution on the support layer; and
curing the coating solution to form a cleaning layer, wherein the curing temperature is between 80° C. and 160° C., and the curing time is between 5 minutes and 90 minutes.

8. The method according to claim 7, wherein the resin comprises polyorganosiloxane having vinyl groups, the curing step forms a network structure through hydrosilylation reaction, such that the cleaning layer has a Shore hardness A between 40 and 90, and the cleaning layer has an elastic modulus between 40 kg/cm2 and 200 kg/cm2.

9. The method according to claim 7, further comprising:
before mixing the resin, the cleaning particles, and the abrasive particles, performing surface modification on the cleaning particles to introduce at least one functional group selected from the group consisting of alkenyl, ether, amide, amino, carboxyl, ester, alcohol, silane, alkoxy, and alkoxysilane groups on the surface of the cleaning particles.

10. The method according to claim 7, wherein the resin is prepared by hydrolysis and condensation reaction of a monomer mixture comprising dimethyldichlorosilane and phenyltrichlorosilane, and the resin has a glass transition temperature between −60° C. and −20° C.

11. The method according to claim 7, wherein the curing temperature and the curing time are cooperatively configured to selectively determine a structural product ratio between a first product structure generated via a first reaction pathway having a first reaction energy barrier, and a second product structure generated via a second reaction pathway having a second reaction energy barrier lower than the first reaction energy barrier.

12. The method according to claim 11, wherein the curing temperature is controlled between 100° C. and 130° C. and the curing time is controlled between 30 minutes and 60 minutes, thereby predominantly generating the second product structure to provide the cleaning layer with an elastic modulus between 40 kg/cm² and 70 kg/cm² and a Shore A hardness between 40 and 50.

13. The method according to claim 11, wherein the curing temperature is controlled between 130° C. and 150° C. and the curing time is controlled between 10 minutes and 30 minutes, thereby predominantly generating the first product structure to provide the cleaning layer with an elastic modulus between 70 kg/cm² and 150 kg/cm² and a Shore A hardness between 50 and 80.

14. A method for cleaning a probe pin, comprising:
providing a decontamination material according to claim 1;
penetrating the probe into the cleaning layer of the decontamination material, wherein a substance adhered to the probe rubs against the abrasive particles in the cleaning layer and is detached from the probe; and
separating the probe from the cleaning layer of the decontamination material, wherein the resin and the cleaning particles actively trap and encapsulate the substance detached from the probe within the resin, thereby mitigating a possibility of the substance re-adhering to the probe.

15. The method according to claim 14, wherein a quantity of the cleaning particles is greater than a quantity of the abrasive particles per unit volume, such that the substance detached from the probe is facilitated to be trapped within the resin by the cleaning particles.

16. The method according to claim 14, wherein the method for cleaning the probe is performed in-situ or on-line, and the probe is not disassembled or separated from a test device during the method.

17. The method according to claim 14, wherein the cleaning layer has an elastic modulus between 40 kg/cm² and 200 kg/cm², and wherein when the probe penetrates into the cleaning layer, the cleaning particles distributed around the abrasive particles synergistically function as micro-dampers to absorb an impact force from the probe, thereby providing a stress dispersion mechanism within the cleaning layer.

18. The method according to claim 14, wherein a surface of each of the cleaning particles comprises at least one specific organic functional group, and the specific organic functional group participates in a cross-linking reaction during curing of the resin to establish an interfacial chemical anchoring between the surface of each of the cleaning particles and a network structure of the resin, thereby mitigating a possibility of the cleaning particles falling out during operation.
